(19) United States
(12) Patent Application Publication
(10) Pub. No.: US 2026/0032865 A1
(43) Pub. Date: Jan. 29, 2026

(54) MODULAR DATACENTER

(71) Applicant: Rexes Corporation, Newark, DE (US)

(72) Inventors: Stephens THÉ, Newark, DE (US); Zachary THÉ, Newark, DE (US)

(73) Assignee: Rexes Corporation, Newark, DE (US)

(21) Appl. No.: 19/280,310

(22) Filed: Jul. 25, 2025

Related U.S. Application Data
(60) Provisional application No. 63/675,730, filed on Jul. 25, 2024.

(51) Int. Cl. H05K 7/20; H05K 5/02

(52) U.S. Cl. CPC H05K 7/20372; H05K 5/0256; H05K 7/20327; H05K 7/20363

(57) ABSTRACT

A modular datacenter has at least one cryogenic datacenter module with server blocks and pipes for providing heat transfer fluid to and from server blocks. At least one cooling generator module is provided that has a pump. Each of the at least one cooling generator module is in fluid communication with the at least one pipe such that a cooled heat transfer fluid is pumped to the at least one server block and a used heat transfer fluid flows back to the at least one cooling generator module. The used heat transfer fluid is cooled within the at least one cooling generator module. A power source is provided in communication with a power input on server boards within the server blocks and the cooling generator module.

### FIELD OF THE DISCLOSURE

The present application relates generally to a modular datacenter that may be transportable and utilized off-grid.

### BACKGROUND

This section provides background information to facilitate a better understanding of the various aspects of the invention. It should be understood that the statements in this section of this document are to be read in this light, and not as admissions of prior art.

A datacenter is the physical embodiment of a cloud system and is typically housed in a building or room containing servers, switches, CPUs, GPUs, memory, routers, networking equipment, high-speed cabling, power systems, and cooling systems. It serves as a hub for remote computing and data storage. Multiple data centers can be networked together and accessible via the internet or other communication networks.

The rapid global expansion of data centers is significantly increasing demands on power resources, potentially straining grid supplies. By 2050, data centers are projected to consume over 10% of global electricity. This surge highlights the urgent need for sustainable solutions to support future growth, especially as CPU and GPU technologies become more power intensive. The advancement of generative AI and cloud computing further amplifies this demand, requiring higher usage of processors and memory to handle the increased data processing needs.

Modern datacenters face numerous challenges that significantly impact their performance and sustainability. These include high energy consumption, substantial operational costs, environmental harm, and complex resource management due to physical space constraints. The need for effective cooling systems, ensuring high availability, and integrating new technologies further add to the burden. While advancements in cooling techniques have shown promise in improving efficiency, the transition to renewable energy sources and efficient resource management remains complex and costly.

Ensuring high availability and minimizing downtime in datacenters requires complex and costly redundancy measures, and implementing effective disaster recovery plans to protect against natural and human-made disasters can be challenging. Expanding datacenter capacity is challenging due to physical space limitations, and balancing and optimizing resource allocation to meet varying demands is complex. Datacenters located far from end-users can experience higher latency, impacting performance, and increasing data traffic can strain network bandwidth, affecting speed and reliability. Integrating new technologies with existing legacy systems in datacenters can be difficult and costly, and keeping up with the fast pace of technological advancements requires frequent upgrades and training. Transitioning to renewable energy sources in data centers is complex and costly but essential for long-term sustainability, and efficiently managing water and other resources used in cooling and other operations is a growing concern. While datacenters have become an integral part of everyday technology, the ability to build and operate them continues to be a struggle.

### BRIEF SUMMARY

There is provided a modular datacenter that has at least one cryogenic datacenter module and at least one cooling generator module. Each of the at least one cryogenic datacenter modules has at least one server block. At least one pipe within cryogenic datacenter module provides a heat transfer fluid to and from the at least one server blocks. Each of the at least one server blocks houses at least one server board. The server boards each have at least one data port and a power input. Cooling generator modules have a pump and are in fluid communication with the pipe within the cryogenic datacenter modules such that a cooled heat transfer fluid is pumped to the at least one server block and a used heat transfer fluid flows back to the at least one cooling generator module. The used heat transfer fluid is cooled within the at least one cooling generator module for reuse. A power source is provided in communication with the power input of the at least one server board and the at least one cooling generator module to provide electricity to operate the modular datacenter.

In one embodiment, the power source is an electrical generation module which generates electricity. Electricity may be generated through the use of a combined heat and power engine powered by natural gas, biogas, or hydrogen, or any other suitable generators such as fuel cells, solar power, wind power, or other suitable electrical generator known to a person skilled in the art.

In one embodiment, an electrical energy storage module is provided in communication with the electrical generation module such that excess electricity generated by the electrical generation module is storable within the electrical energy storage module for later use as the power source. The electrical energy storage module may house at least one lithium phosphate battery and at least one supercapacitor or any other type of suitable battery or electrical storage known to a person skilled in the art.

In one embodiment, a microgrid energy management module is provided for controlling the flow of electricity through the modular datacenter. This includes controlling the flow of electricity to and from the electrical storage module, flow from the electrical generation module to locations for use, and protections to prevent surges.

In one embodiment, the cooling generator module has an absorption chiller for reducing the temperature of the heat transfer fluid.

In another embodiment, the cooling generator module has a liquid nitrogen generator for capturing and liquefying atmospheric nitrogen for use as the heat transfer fluid. The cooling generator may utilize a liquid nitrogen cycle, incorporating multi-stage compression and Joule-Thomson expansion to achieve cryogenic cooling down to approximately 77K (−196° C.). Alternatively, when liquefied natural gas is available, its latent heat of vaporization may be harvested to provide cryogenic cooling near 111K (−162° C.), leveraging the phase-change energy during liquefied natural gas regasification.

In one embodiment, a liquified energy storage is provided. The liquid energy storage has at least one storage tank for natural gas or hydrogen. The at least one storage tank is in fluid communication with the electrical generation module such that a fuel is provided to operate the combined heat and power engine.

In one embodiment, each of the at least one server blocks is shaped as a cube.

In one embodiment, each of the at least one server blocks are stacked on a series of shelves positioned on a first side wall and a second side wall of the at least one cryogenic datacenter module.

In one embodiment, the at least one pipe is positioned under an elevated platform.

In one embodiment, each of the at least one server boards are securely mounted on a slotted mounting plate with all of the at least one data ports and the power input connected to a DC bus bar.

In one embodiment, each of the at least one server blocks has an access panel. The access panel has a first plumbing port for introduction of heat transfer fluid to the at least one server block, a second plumbing port for the heat transfer fluid to flow out of the at least one server block, an electrical port for connection to the power source and the power input of the at least one server boards, and at least one data interface for connecting to the at least one data ports of the at least one server board for storing and computing data.

In one embodiment, each of the at least one cryogenic datacenter module and cooling generator module are contained within a shipping container.

### BRIEF DESCRIPTION OF THE DRAWINGS

These and other features will become more apparent from the following description in which references are made to the following drawings, in which numerical references denote like parts. The drawings are for the purpose of illustration only and are not intended to in any way limit the scope of the invention to the particular embodiments shown.

FIG. 1 is a schematic view of a modular datacenter.

FIG. 2 is a perspective view of a modular datacenter.

FIG. 3 is a schematic view of electrical connections with a modular datacenter.

FIG. 4 is a perspective view of a cryogenic datacenter module which forms a part of a modular datacenter.

FIG. 5 is a perspective view, in section, of the cryogenic datacenter module shown in FIG. 4 with the external housing and insulation removed.

FIG. 6 is a detailed perspective view of a lower portion of the cryogenic datacenter module shown in FIG. 4.

FIG. 7 is a perspective view of the cryogenic datacenter module.

FIG. 8 is a perspective view of a cryogenic server block.

FIG. 9 is a perspective view of a server board housed within a cryogenic server block.

FIG. 10 is a perspective view of a server board housed within a cryogenic server block.

FIG. 11 is a perspective view of a cryogenic server block and server board.

### DETAILED DESCRIPTION OF THE PREFERRED EMBODIMENTS

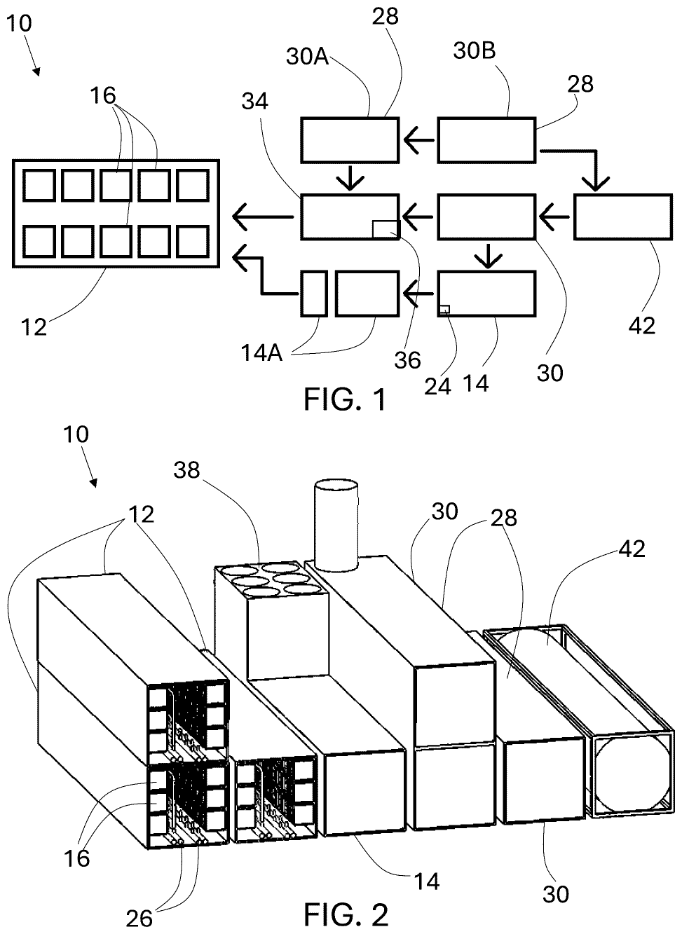

A modular datacenter, generally identified by reference numeral 10, will now be described with reference to FIG. 1 through FIG. 11.

Given that thermal management is a critical bottleneck in high-performance computing, selecting the appropriate heat transfer morphology and cooling fluid is essential for efficient heat removal from electronic devices. In this context, morphology refers to the form and structure of the cooling system, including the arrangement and design of its components. It involves studying how the physical shape and configuration of the system affect the flow and distribution of the cooling fluid and the efficiency of heat transfer. Morphology pertains to the overall layout and design characteristics that influence the performance of the cooling process. The goal is to design a system based on robust fluid dynamics and heat transfer principles to optimize the fluid heat transfer coefficient, considering the fluid's operational temperature and pressure while ensuring safety and efficiency. Unlike open tanks that rely on natural or forced convection of dielectric fluids, the present invention may utilize high-flow-rate forced convection within a pressurized chamber. The internal configuration of server blocks is crafted to enhance heat transfer and fluid dynamics, effectively dissipating heat generated by IT equipment, particularly from the most heat-intensive surfaces.

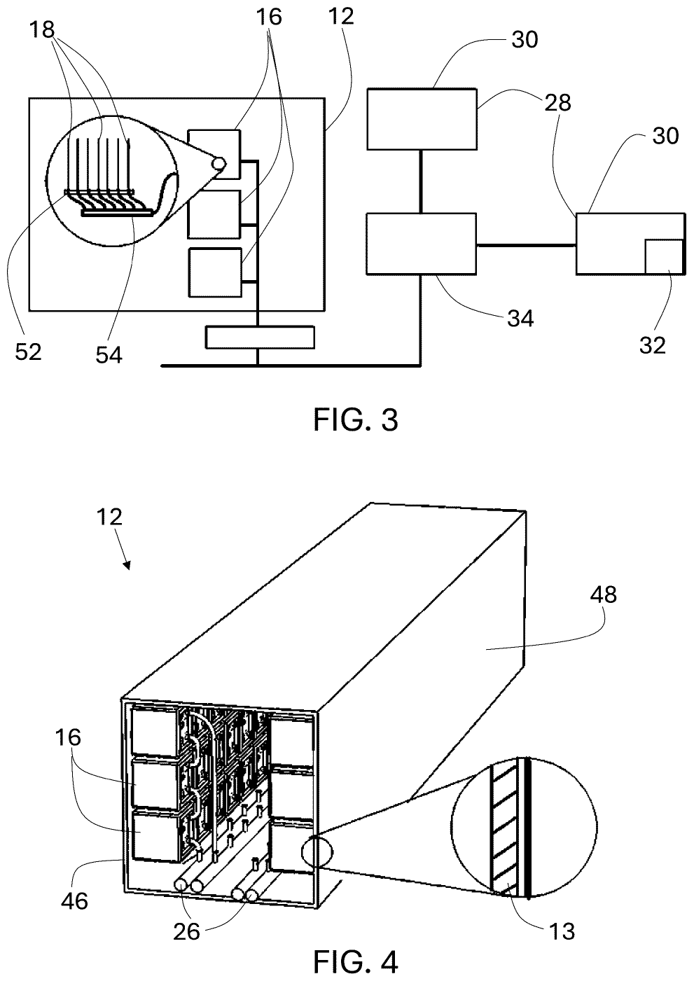

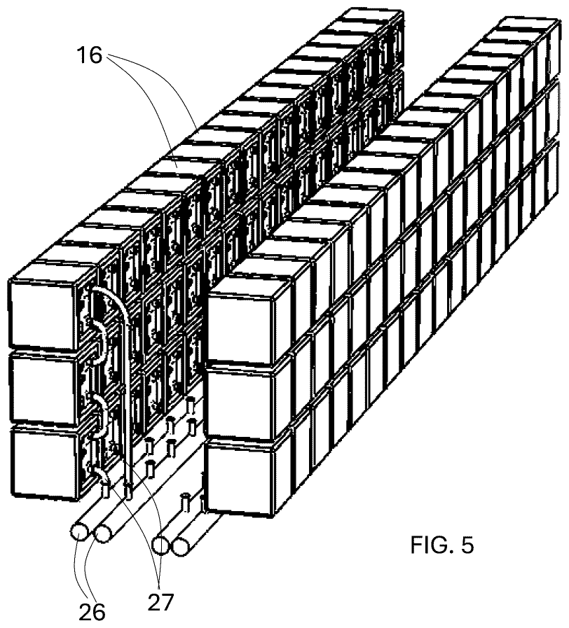

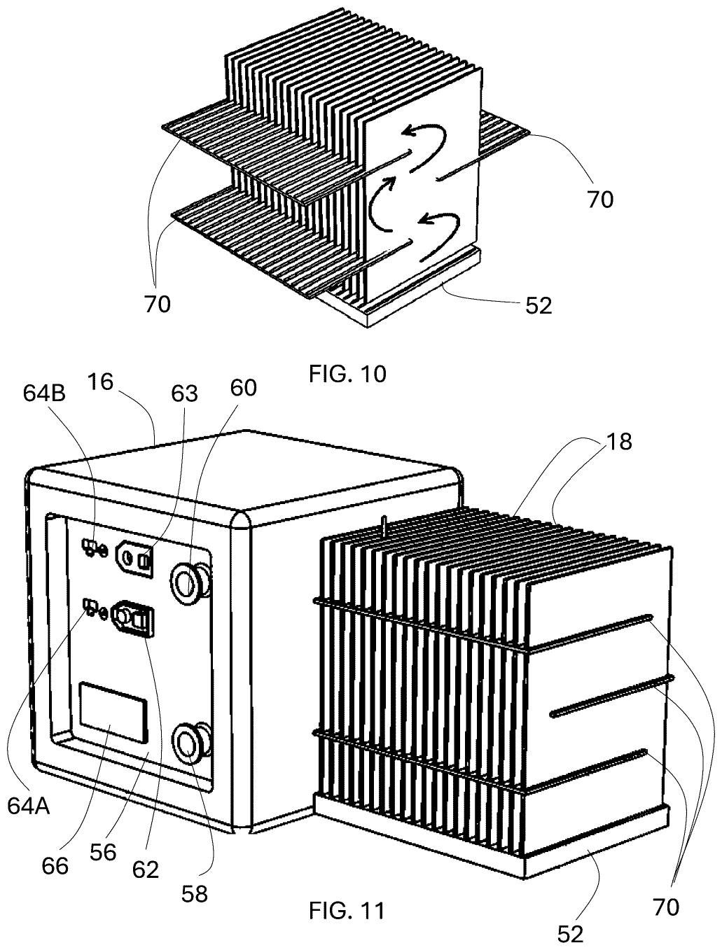

Referring to FIG. 1, a modular datacenter 10 includes at least one cryogenic datacenter module 12 and at least one cooling generator module 14. Cryogenic datacenter module 12 may be made of any suitable material including, but not limited to, stainless steel, composite materials, or injection-molded polymers. Foam insulation 13 can be used to help reduce heat intrusion. Each cryogenic datacenter module 12 has at least one server block 16 that is used for storing and computing data. Cryogenic datacenter module 12 can support a high number of servers and can provide advanced safety and monitoring systems to maintain operational integrity. Referring to FIG. 9, FIG. 10, and FIG. 11, server blocks 16 each have at least one server board 18 with data ports 20 and power inputs 22. Server blocks are well known in the industry and a person skill will understand how they operate. Additional components, including switches, CPUs, GPUs, memory, routers, networking equipment, and high-speed cabling are included within cryogenic datacenter modules 12, a schematic of which is shown in FIG. 3. The interior climate of cryogenic datacenter modules 12 is controlled to maintain low temperatures and low humidity to prevent condensation and ice formation. To help maintain temperatures, cryogenic datacenter module 12 is preferably insulated with foam, insulating blankets, or other appropriate insulation methods to minimize external heating. In one embodiment, the internal temperature of cryogenic datacenter module 12 is maintained at 4° C. with relative humidity below 20% to prevent condensation and icicle formation. Oxygen level may also be monitored and maintained at approximately 20% for safety purposes. Referring to FIG. 2, cooling generator module 14 has a pump 24 that is used to circulate heat transfer fluid from cooling generator module 14 to server blocks 16. Cooling generator modules 14 are in fluid communication with pipes 26, shown in FIG. 4, FIG. 5, and FIG. 6, positioned in cryogenic datacenter modules 12 that allow for the flow of heat transfer fluid through cryogenic datacenter module 12 and through server blocks 16 for cooling server blocks 16. Used heat transfer fluid is returned to cooling generator module 14 and cooled within cooling generator module 14. It will be understood by a person of skill in the art that various valves, pumps, reducers, safety release valves, sensors, and flow control mechanisms may be included for controlling flow through pipes 26 and server blocks 16. A person of skill would understand how to properly incorporate these elements as they are well known within the industry. Referring to FIG. 1, a power source 28 is provided in communication with power inputs 22 and cooling generator module 14 to allow for operation of modular datacenter 10.

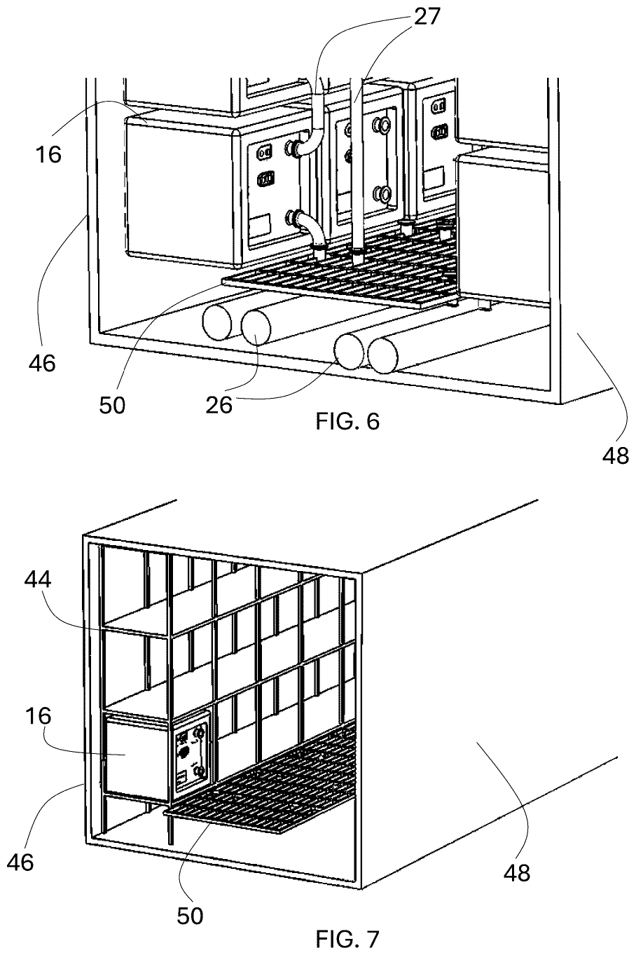

Referring to FIG. 6 and FIG. 7, to aid in limiting access to pipes 26 while allowing access to cryogenic datacenter modules 12, pipes 26 may be positioned under an elevated platform 50. Plumbing, electrical and data transfer infrastructure includes valves, pumps, solenoid valves, pressure regulator valves, sensors, pressure relief valves, including control circuits, electrical wires, and data conduits may all be housed under elevated platform 50.

Referring to FIG. 2, cooling generator module 14 may utilize an absorption chiller 38 for reducing the temperature of heat transfer fluid flowing through cooling generator module 14. Absorption chiller 38 may utilize waste heat from power source 28 to power absorption chiller 38. As an example, a commercial absorption chiller can use 13 MMBtu/hr of heat generated by power source 28 and can be operated with steam, hot water, or direct natural gas/hydrogen firing to produce 1200 tons of chilled fluid at sub-zero temperatures. By reusing waste heat from power source 28, electrical and thermal recovery efficiency can be greatly improved. Cooling generator module 14 may utilize a liquid nitrogen generator 40 for capturing and liquefying atmospheric nitrogen for use as a heat transfer fluid. Liquid nitrogen has a temperature of −196° C. Liquid nitrogen generator 40 processes ambient air which contains 80% nitrogen, using a nitrogen separator, dryer, condenser, and storage system to produce the liquid nitrogen. Energy consumption of 0.2 kWh per kg of liquid nitrogen can be expected. In a closed loop system, nitrogen vapor can be recondensed to remove heat and recycled as fluid, with fresh liquid nitrogen being generated for replenishment. While liquid nitrogen evaporation provides rapid cooling, converting all evaporated liquid nitrogen back into liquid may be doable but is often impractical. As an example, 1200 tons of cooling as 12000 BTU per ton would evaporate 14 MMBtu/hr of liquid nitrogen. With an enthalpy of evaporation of 200 BTU/kg, this equals 72 tons of liquid nitrogen per hour or 400 GPM. Given a vapor density of 0.8 Nm³/kg, this translates to 60000 Nm³/kg or 160 m³/min. The necessary centrifugal pump would require approximately 4000 hp or 3 MW, consuming a significant portion of the produced electricity. It is, therefore, more practical to utilize liquid nitrogen to chill cooling fluid to low temperatures through a heat exchanger rather than relying solely on liquid nitrogen evaporation for cooling purposes.

Cryogenic datacenter module 12 may operate cryogenically, from subzero Celsius to liquid nitrogen temperatures of 77K. Cryogenic cooling is defined by temperatures below the freezing point of water. In one embodiment, this is achieved by providing absorption chiller 38 to achieve temperature from −5° C. to −70° C. A single phase heat transfer fluid may be circulated through cryogenic datacenter module 12 and cooling generator module 14 to remove heat. In one example, the heat transfer fluid has a total capacity of 1200 tons of cooling per cryogenic datacenter module, circulating 6000 GPM of cooling fluid with a temperature increase of 5° C. Heat transfer between heat transfer fluid and absorption chiller 38 is preferably facilitated by heat exchangers. In another example, for lower temperatures, a dual cooling loop with a jacketed pipe or heat exchanger can be used. Cooling fluid may be provided to a first pipe and a two phase liquid nitrogen in a jacketed pipe. The ratio of liquid nitrogen to cooling fluid determines the temperature achieved. At the extreme, modular datacenter 10 may become a two-phase nitrogen system, where pure 400 GPM of liquid nitrogen is pumped into the cryogenic datacenter modules. This is likely to require stringent safety measures to achieve temperatures as low as 77K.

In one embodiment, cryogenic datacenter module 12 may receive 45 kW of power and require 12 tons of cooling a 3.5 kW per ton. With inlet and outlet pipes having a 2 inch diameter and a flow rate of 60 GPM, at half the heat capacity of water (4.2 BTU/gal.° F.), a temperature increase of 16° F. may be necessary. Therefore, liquid enters absorption chiller 38 at a temperature of −27° F. and exits at −11° F. This can allow modular datacenter 10 to operate at around 250K.

As nitrogen is an asphyxiant and can cause skin burns, safety measures may become important. Oxygen sensors, warning signals, fire suppression systems, and pressure relief valves that vent to the outside should all be considered. Warning signals to alert operators of low oxygen may also be appropriate. Utilized dehydrated fresh air can be used to replenish oxygen levels as needed. When liquid nitrogen is used, it should be in a closed loop system, with nitrogen pumped from the bottom of cryogenic datacenter module 12 and exiting at the top. Plumbing may be sealed with appropriate fittings and connectors to prevent nitrogen from escaping into cryogenic datacenter module 12. Nitrogen and oxygen levels should be checked prior to personnel entering modules and fresh, dry air may be introduced during maintenance such that temperatures are maintained near 0° C.

It will be understood by a person skilled in the art that other types of cooling methods may be used. Evaporation coolers, vapor compression chillers, and gas powered absorption chillers are all viable options. Evaporation coolers are useful for air cooled datacenters but require large installations and consume significant quantities of water for cooling. This tends to lead to the generation of significant quantities of wastewater. Vapor compression chillers include screws, scrolls, reciprocating, and centrifugal types which are require motors or engines to operate. Gas powered absorption chillers utilize more expensive fuel sources and can reduce the overall efficiency of modular datacenter 10 if used.

To help address the increasing challenges of high-performance computing, the use of cryogenic cooling may allow operation of modular datacenter 10 at temperatures below the freezing point of water, or as low as 77K, using liquid nitrogen. The use of liquid nitrogen as a heat transfer fluid may provide performance enhancements more than 50% when temperatures drop to 100K. Cryogenic cooling can help improve thermal and electrical conductivity, reduce resistive heating, and enhance heat dissipation. This may support the development of more efficient and sustainable datacenters. Operating at lower temperatures may also provide more leeway to prevent server overheating thresholds.

Power source 28 may be any suitable source known to a person skilled in the art. While the use of renewable resources is preferred, power source 28 may be a connection to the local electrical power grid or to a generator. Power source 28 may be an electrical generation module 30 that generates electricity for use within modular datacenter 10. Electrical generation module 30 may create electricity through the use of a generator, a combined heat and power engine 32 powered by natural gas or hydrogen, solar power, wind power, or any other suitable mechanism known to a person skilled in the art. An off-grid datacenter can provide a reliable solution for areas with limited power infrastructure by utilizing electrical generation module 30. This can include a combination of generator, combined heat and power engine, solar power, wind power, and other renewable resources. Electrical generation module 30 can provide direct DC power to server blocks 16 and any other portion of modular datacenter 10 requiring power to operate. When a combined heat and power engine 32 is used, waste heat from combined heat and power engine 32 may be used to provide power to absorption chiller 38 in cooling generator module 14. In many of the embodiments shown, multiple electrical generation modules 30 are utilized. Multiple electrical generation modules become more useful when working with multiple different types of power generation. For example, one electrical generation module 30 may be used for generating power using renewable resources such as wind, solar, or through using waste energy and a second electrical generation module may be used to operate a combined heat and power engine. It will also be understood by a person skilled in the art that all power generation may occur in a single electrical generation module. Referring to FIG. 1, electrical generation module 30A incorporates wind and solar power generation and electrical generation module 30B utilizes waste heat as an energy source to create usable fuels which can be stored for later use or used to power combined heat and power engine 32 directly.

Combined heat and power engine 32 captures thermal energy and can provide air pollution control. Conventional combined heat and power engines can generate over 4.4 MW of electricity and 13 MMBtu/hr of heat from 36 MMBtu/hr of fuel. The fuel source may be liquified natural gas, renewal natural gas made from organic waste or other sources, or hydrogen. Hydrogen may be produced by solar or wind-powered electrolysis to create zero carbon emissions. Selective catalytic reduction technology can be included that converts NOx pollution into harmless diatomic nitrogen. An exhaust chimney may be provided to allow for the waste, including diatomic nitrogen, to escape from combined heat and power engine 32.

The ability to store created energy can greatly improve reliability of electrical supply for modular datacenter 10. An electrical energy storage module 34 may be provided to store excess electricity for later use as a power source. This is beneficial when solar power is utilized for energy generation as excess electricity can be stored for use when solar power is non functional. Wind power also benefits from having the ability to store excess electricity for later use when wind speeds are insufficient to meet demand. Electrical energy storage module 34 may house at least one lithium phosphate battery and at least one supercapacitor which can be used for electrical storage purposes. It will be understood by a person skilled in the art that different types of batteries may be used. When modular datacenter 10 is equipped with electrical energy storage module 34, there may be improved resiliency in the face of intermittent renewable sources, such as wind and solar. This may allow for uninterrupted service even in regions with unreliable local grids and can help in offering a robust framework for data services in remote or developing areas. Electrical energy storage module 34 helps to stabilize power supply, store intermittent renewable energy, and manage peak demand loads. Electrical energy storage module 34 may be equipment with battery management tools, fire suppression, and control systems.

To minimize external environmental impacts, prioritize energy efficiency, and maintain a low carbon footprint, it is preferred that fuel used to provide power and operate elements within modular datacenter 10 be renewable products including, but not limited to, renewable natural gas such as biogas and syngas, hydrogen, and green fuels. Renewable natural gas, biogas, and syngas may be generated from landfill gas, agricultural waste, food waste, wastewater biosolids, and other organics using methods known to a person of skill in the art. The incorporation of solar panels, wind turbines, and advanced battery storage systems can help to reduce carbon emissions and water pollution.

A microgrid energy management module 36 may be provided for controlling the flow of electricity through modular datacenter 10. This includes controlling the flow of electricity to and from electrical storage module 34, flow from electrical generation module 30 to locations for use, and protections to prevent surges. Microgrid energy management module 36 becomes more beneficial when multiple electrical sources are used to create electricity as microgrid energy management module will manage the flow of electricity from the various sources to electrical storage module 34 and to portions of modular datacenter 10 requiring power. Microgrid energy management module 36 may act as a core electrical management system for modular datacenter 10 and can be used to oversee and control power generation and demand response activities to ensure the safe, effective, and reliable operation of both electrical loads and cooling systems. Microgrid energy management module 36 may be included as a part of electrical energy storage module 34 for enhanced coordination. For AI applications characterized by rapidly fluctuating electrical demand, a hybrid energy storage system comprising supercapacitors and batteries may be employed to accommodate transient load variations. The supercapacitors address ultra short duration spikes (less than 15 milliseconds), while the batteries can manage longer duration load increases on the order of minutes. This configuration helps to smooth out load fluctuations and electrically decouples electrical generation module 30 from fast changing demand, thereby maintaining stability and performance. An uninterruptible power supply mechanism can help maintain continuous operation by utilizing a control system and an automatic transfer switch to monitor electrical system health and respond to power failures or abnormalities.

Microgrid energy management module 36 may also control and monito cooling processes in modular datacenters 10. A feedforward control system for server block 16 cooling can proactively manage the temperature of server blocks 16 by anticipating increases in IT computational demand. In modular datacenter 10, the current server block 16 temperature is continuously monitored to ensure it remains within safe limits. Concurrently, microgrid energy management module 36 predicts upcoming spikes in computational load, which would typically result in higher heat generation. In anticipation of these spikes, flow rate of cooling fluid increases and chills the fluid further to enhance its heat absorption capacity. By adjusting these parameters preemptively, the feedforward system ensures that server blocks 16 are kept at a stable and safe temperature even as computational demands rise, thereby preventing overheating and maintaining optimal performance and reliability. Thermal throttling may be implemented to maintain a safe balance between power and cooling capacities.

Referring to FIG. 3, the use of DC architecture to coordinate power management may be beneficial. Maintaining DC architecture eliminates the need for multiple transformers and avoids energy losses from power conversion. This approach can also reduce the number of required components which can cut both capital and maintenance costs and can minimize the risk of voltage surges and power irregularities. This can help to create a more consistent and reliable power supply. The use of multiple AC-DC conversions in datacenters can result in up to 10% power loss which also contributes to additional heat generation, thus reducing efficiency. By running DC power throughout modular datacenter 10, power loss is minimized and efficiency is increased. A person of skill will understand how to appropriately connect modules and components of modular datacenter 10 to supply power as needed.

A liquified energy storage 42 may be provided for storage of fuel to operate power source 28 and electrical generation module 34 when needed. Liquified energy storage 42 has at least one storage tank for natural gas or hydrogen. Storage tanks are in fluid communication with electrical generation module 34 such that fuel is provided to operate combined heat and power engine 32 in electrical generation module 34 or other power sources 28.

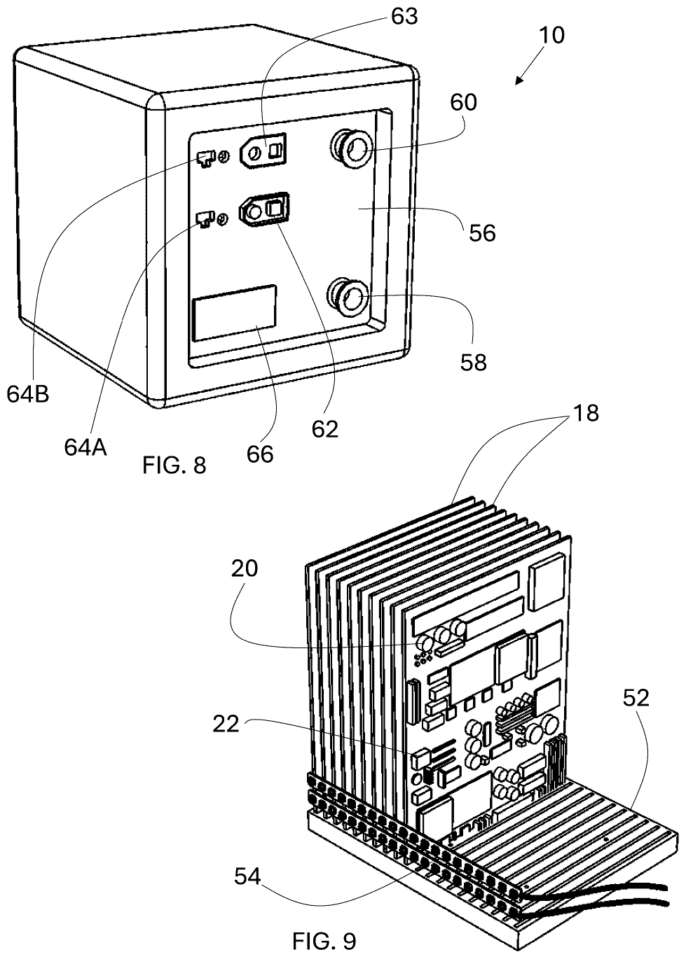

Referring to FIG. 8, server blocks 16 are preferably shaped as cubes to allow for more efficient stacking and uniformity. Referring to FIG. 7, server blocks 16 may be stacked on a series of shelves 44 that are positioned on a first side wall 46 and a second side wall 48 of cryogenic datacenter modules 12. In one embodiment, server blocks 16 include twenty serve boards 18. Each server board 18 can contain two sets of servers for a total of 40 servers per server block 16. This design can help to streamline for maximum power density and cooling, with a calculated heat flux of 2 W/cm² which is well below the boiling point of 3M dielectric fluid and allows for single-phase operations. In the embodiments shown in FIG. 4 and FIG. 5, cryogenic datacenter module 12 can house 108 server blocks, arranged in 2 rows of 18 wide and 3 high. Each cube may provide 45 kW of power, supporting 40 server boards 18 each. Server boards 18 found within server blocks 16 may be securely mounted on a slotted mounting plate 52 with all of the at least one data ports 20 and power inputs 22 connected to a DC bus bar 54. DC bus bar 54 serves as a metallic strip or bar that conducts electricity within a distribution board or panel. This helps to efficiently and safely distribute power. This allows for simpler communication between server boards 18 located within a server block 16 and simplified electrical communications. Referring to FIG. 8, server blocks 16 may have an access panel 56. Access panel 56 has a first plumbing port 58 for introducing heat transfer fluid to server block 16, a second plumbing port 60 for heat transfer fluid to flow out of server blocks 16, an electrical inlet 62 and an electrical outlet 63 for connection to power source 28 and power input 22 of server boards 18, and at least one data interface 64A and 64B for connection to the data ports 20 of the server boards 18 for storage and computing data. Data interface 64A in a data inlet port and data interface 64B is a data outlet port. The ability to operate without cooling fans and on DC voltage, server blocks 16 feature streamlined circuitry, analogous to a circuit board installed in a motherboard socket, engaged with clasps on each end, and snapped tight into each slot. Access panel 56 may also have a diagnostic display 66 which can provide status updates, alerts, and warning signals. Other information may also be displayed on diagnostic display 66. When a DC bus bar 54 is present, electrical port 62 may connect power source 28 to DC bus bar 54 and data interface 64 may connect to DC bus bar 54. Server blocks 16 may include dedicated server hardware, CPUs, GPUs, RAM, storage, network interfaces, PCI, and expansion slows. Server blocks 16 in the shape of cubes may function modularly in a compact form. These high power, high cooling intensity designs may overcome traditional datacenter inefficiencies including the need for large spaces for hot and cold aisles in air cooling and can offer a simpler setup than immersion cooling. Server blocks 16 can help to streamline operations, protect server circuitry, provide improved heat removal, and improve serviceability. Additionally, server blocks, particularly in cube shape, can be stacked for better space utilization and can be highly scalable, allowing for additional modules and server blocks to be added as demand increases.

It will be understood by a person skilled in the art that alternative server blocks 16 may be utilized or configured differently, such as quantum computing or other advanced computing technologies where improvements in chip fabrication allow for more qubits or processors to be housed in smaller spaces. Regardless of the form, it is preferable that the design of server blocks 16 be scalable and include compact configurations. Future computing systems may be smaller and more powerful. If different shapes are required, server blocks 16 may be any suitable size or shape while still providing high intensity power generation and cooling systems.

Server blocks 16 can utilize a variety of network and data connectors to facilitate communication, data transfer, and connectivity. Common network connectors include Ethernet ports like RJ-45, SFP, and fiber optic connectors. For data connectors, servers often use interfaces such as SATA, PCIe, and other high-speed connections. These connectors can provide efficient server connections to networks, storage systems, and various peripherals, supporting robust and high-performance data center operations. Commercial quick-connect modular or custom connectors, along with structured or unstructured cabling, can be employed according to ANSI/ISO standards and specific demands.

The cooling of electronic components can be achieved through two primary methods: direct and indirect fluid cooling. Direct fluid cooling involves heat transfer fluid making direct contact with circuit surfaces which offers the best heat transfer, as seen in immersion cooling or forced convective cooling. This method poses risks to sensitive circuitry. Indirect fluid cooling, on the other hand, utilize heat pipes, heat exchangers, or cooling fins to remove heat without the fluid touching circuitry. Heat transfer fluid can be circulated directly through cold plates that are in contact with heat-producing components in server blocks 16. Heat transfer in this method is limited by the thermal conductivity of the cooling plate, air gaps, or the conductivity of conductive tape. Cryogenic heat pipes, made of copper and containing fluids such as helium, methanol, or acetone, can operate at extremely low temperatures ranging from −50° C. to −200° C. using nitrogen. These pipes can significantly enhance cryogenic cooling, especially where additional cooling is required, with Boyd heat pipes capable of increasing heat transfer performance up to 200 times that of copper, aluminum, or graphite. If indirect cooling is used, multiple tubes can be connected to server board 18 heat exchangers.

Server blocks 16 are cooled by heat transfer fluid entering first plumbing port 58, circulating through server block 16, and exiting through second plumbing port 60. Server blocks 16 are provided in fluid communication with pipes 26 through secondary pipes that fluidly connect server blocks 16 to pipe 26. As shown in FIG. 5, heat transfer fluid may travel from pipe 26 to a secondary pipe 27 and through multiple server blocks 16 before returning to pipe 26. It will, however, be understood by a person skilled in the art that fluid flow may be directed to individual server blocks 16 or multiple server blocks 16 depending on the type of heat transfer fluid and cooling needs of server blocks 16. Quick connect pipe fittings can be used to provide for easier installation of server blocks with fluid flow requirements.

Server blocks 16 act as an enclosed server housing designed for efficiency, easy installation, and easy maintenance in high-density configurations. First plumbing port 58 and second plumbing port 60 allow for heat transfer fluid to travel through server blocks 16 to maintain appropriate temperatures. This helps to prevent overheating, reduce resistive loss, and supports higher clock speeds for optimal performance. In one embodiment, it offers a high cooling rate with only 45 kW of power and 12 tons of cooling capacity for efficient heat dissipation and the safeguarding of critical components. The enclosed design helps to protect against environmental dust, humidity, and vibration which can reduce handling damage. The compact, stackable for improves space usage and can allow for up to 40 server boards 18 to be held within a single server block 16. Factory assembly may help to minimize construction errors and optimize cable management to improve integration, certification, and sealing for rapid on site installation, lower costs, and preventing accidental disconnections. The uniformity of server blocks 16 can enhance field serviceability by eliminating the need for tanks or fans since front access panels provide all required connections. This can help minimize field labor and upkeep, reduce downtime, and cut maintenance costs.

As power requirements fluctuate with demand, generated heat also varies. The thermal-hydraulic balance and transient temperature are influenced by factors such as heat sources, fluid flow, geometry, and non-steady state conditions. While power consumption changes linearly with CPU and GPU utilization, the transient temperature exhibits nonlinear behavior. This behavior depends on variables like volumetric flow rate, hydraulic flow profile, and the rate of heat generation, which are functions of Reynolds, Nusselt, and Prandtl numbers. The transition from an idle state to a peak state result in a corresponding temperature change. Computational fluid dynamic modeling can simulate these temperature and flow profiles which can be especially crucial for AI applications characterized by rapidly fluctuating electrical demand and temperature rise.

Heat removal rate is determined by optimizing the overall heat transfer coefficient of fluid through forced convection, which efficiently removes heat between first plumbing port 58 and second plumbing port 60. In the embodiment shown in FIG. 10 and FIG. 11, server blocks 16 with server boards 18 may have horizontal baffles 70 to assist in redirecting and guide cooling fluid flowing through server block 16 and around server circuits. Horizontal baffles 70 can optimize airflow patterns, increase velocity and turbulence, minimize stagnant pockets, and enhance overall heat transfer efficiency. The effectiveness of heat removal depends on several factors including the physical properties of heat transfer fluid (density, heat capacity, thermal conductivity, and kinematic viscosity), server geometry, thermal properties of circuit surfaces, and the thermal conductivity of various circuit materials. Additional considerations include boundary layer behavior, the Leidenfrost effect, phase changes, conductive pastes, and heat pipes. The forced fluid design preferred in modular datacenter 10 helps to ensure optimal flow, achieving a Reynolds number exceeding 2900. This indicates turbulent flow where inertial forces dominate over viscous forces. It is preferable that the Nusselt number be 100 or greater. The Nusselt number correlates head exchange between solid surfaces and their surrounding fluids and indicates convective turbulent flow for effective heat transfer. This can help identify flow characteristics that optimize heat transfer, including manipulating surface roughness, flow velocity, and configuration. Higher Nusselt numbers suggests a thinner boundary layer, influencing thermal distribution across the boundary layer thickness, thus bridging theoretical calculations and practical designs. Chaotic mixing and turbulent velocity fluctuations disrupt thermal stratification and localized hot spots, enhancing heat dissipation at thermally critical components like CPUs and GPUs. If liquid nitrogen is used, surface heat transfer should be adjusted to minimize the Leidenfrost effect, where the surface temperature is much higher than the liquid's boiling point to create an insulating vapor layer. Cooling fins can increase heat exchange area between the surface and the fluid but also add volume. In server blocks 16, where space may be limited, selecting the right geometry and material with high thermal conductivity is important for optimizing heat removal. Choosing appropriate heat transfer fluids, whether single phase or two phase, optimizing flow path to avoid stagnation, and fine tuning operating conditions can maximize cooling efficiency.

The modular nature of the components of modular datacenter 10 allows for easier transport, building, and scalability of a datacenter. Each of the cryogenic datacenter modules 12, cooling generator modules 14, electrical generation module 30, electrical energy storage module 34, microgrid energy management module 36, liquified energy storage 42, and any other appropriate component may be housed within a shipping container such as a seacan. It will be understood by a person skilled in the art that custom sized shipping containers may be created for each module. This allows for larger and smaller module units to be built to allow for greater customization and flexibility. Each module may be built off site and equipped with high power and cooling capacities, as needed, to operate modular datacenter 10. Each server block 18 may also be constructed and placed within cryogenic datacenter modules 12 off site. Each server block 18 acts as a fully enclosed IT building block with built in cooling to allow for high-density packaging of server blocks 18 within cryogenic datacenter module 12, simplified serviceability, and simplified replacement of server blocks 18 when needed. When housed in shipping containers and built off site, the various components can be easily moved and set up, virtually creating the ability to place a container and connect the power and fluid transfer connections to allow for use. This also allows modular datacenter 10 to be enlarged by simply adding more components and connecting them to existing components. For example, a builder may start with a single cryogenic datacenter module 12 and cooling generator module 14 but may choose to later add additional cryogenic datacenter modules 12, cooling generator modules 14, electrical generation module 30 for off grid use, electrical energy storage module 34, microgrid energy management module 36, and liquified energy storage 42 as computing and storage requirements, electricity needs, and other parameters change. Land use can potentially be reduced by stacking shipping containers.

In one embodiment, pipes 26 have a diameter of 8 inches which enables the pumping of 3000 GPM of heat transfer fluid. If a single phase dielectric fluid is used, temperature may be cooled down to −33° C. For two phase nitrogen, system may operate at a minimum pressure of 300 psi with pressure relief valves set at 2000 psi. Each server block 16 may have either liquid nitrogen or single phase heat transfer fluid flowing through it. Additional secondary pipes having a diameter of 1 to 2 inches may be used for pumping heat transfer fluid at a rate of 20 to 60 GPM to transfer 20 to 30 tons of cooling for supporting electrical loads of 70 to 100 kW. When 108 server blocks 16 are used, total flow rates may range from 2000 to 6000 GPM. When using liquid nitrogen with phase change, 60 tons of cooling may be achieved. Effective cooling management can be important to reduce hotspots and extend equipment life. Valves may be provided at the bottom of server blocks 16 to aid in fluid drainage if needed.

Different locations for modular datacenter 10 may requirement different numbers of components and needs can change over time. For example, a modular datacenter 12 built in a remote area is more likely to require electrical generation module 30, electrical energy storage module 34, and liquified energy storage 42 as these resources may be scarce in a rural location. On the other hand, a modular datacenter 12 built in an urban area may be able to rely on direct connections to the electricity grid and fuel lines such that fewer components are required to create a successful datacenter.

Modular datacenter 10 allows for deployment in diverse environments, such as open fields and parking lots, without the need for traditional building structures. It can support robust operations through its integrated energy generation and storage systems, and the design eliminates the need for traditional hot and cold aisles which simplifies server setups into compact, stackable cubes. Cubes facilitate easy upgrades and minimize the risk of installation errors, while quick-connect ports ensure rapid serviceability. In addition, modular datacenters 10 may operate off-grid with renewable energy sources, such as wind and solar, which improve resiliency and provide backup power suitable for datacenter requirements. The use of various and varying modules allows modular datacenter to be built to builder and operator specifications while allowing the formation of a resilient and sustainable datacenter. Modules can enable simplified connectively for rapid deployment. Customization can be achieved by choosing which modules to incorporate into modular datacenter and adding more modules as demand grows. The use of shipping containers as outer housing for modules aids in withstanding exposure to elements with building external structures or buildings for the housing of a datacenter. Additional electrical generation modules 30, cooling generator module 14, electrical energy storage modules 34, cryogenic datacenter modules 12, microgrid energy management module 36, and liquified energy storage 42 may be shipped and seamlessly integrated as needed to increase capacity and keep up with demand.

In the embodiment shown in FIG. 2, modular datacenter 10 includes three cryogenic datacenter modules 12 with each containing multiple server blocks 16. As can be seen, cryogenic datacenter modules 12 may be stacked on top of each other. There is also included a cooling generator module 14 which is equipped with an evaporator which may be used to dissipate heat. Evaporators are well known to a person of skill in the art. The single cooling generator module 14 is connected to the three cryogenic datacenter modules 12 and is capable of providing sufficient cooled heat transfer fluid to all three cryogenic datacenter modules 12. An electrical generation module 30 acts as power source 28 and is equipped with an exhaust chimney. An electrical energy storage module 34 and microgrid energy management module 36 are combined into a single shipping container and are connected to the rest of the modular datacenter as needed. A liquified energy storage 42 is also provided to provide fuel to electrical generation module 30. It will be understood by a person skilled in the art that various connections may be made between modules to create a working datacenter. It will further be understood that different numbers of various modules may be used to create different variations of modular datacenter. As is shown, the numbers of various modules may vary and a single cooling generator module 14 may be capable of supporting multiple cryogenic datacenter modules 12. Providing additional electrical generation modules 30, electrical energy storage modules 34, and liquified energy storage 42 can increase electrical generation capacity, electrical storage capacity, and fuel capacity for modular datacenter 10 use.

There are many potential benefits to the use and operation of modular datacenter 10, including:
Modular datacenter 10 can utilize renewable energy sources and innovative waste management practices to achieve net-zero carbon emissions to support sustainable operations without comprising performance.
Modular datacenter 10 can utilize a standardized shipping containers. This allows for rapid deployment and reconfiguration based on the immediate needs of the builder/operator and makes it adaptable for geographical challenges that may arise. Geographical challenges relate to ground conditions that may be present at the building site. Different ground conditions may necessitate different positioning or deployment of modules.
Modular datacenter 10 may be operated independently of traditional power grids using a combination of renewable energy sources and advanced energy storage systems. This can improve reliability in areas with unstable or unavailable grip power.
Cryogenic cooling technologies may enhance computing performance by operating at significantly lower temperatures, improving thermal efficiency and power consumption, and providing greater temperature latitude before reaching a circuit's upper threshold.
The use of modular, compact form factor, block-based architecture helps to simplify installation, maintenance, and scalability while minimizing physical footprint and maximizing performance.
Modular datacenter 10 is designed to be interoperable, allowing an organization to deploy a single ecosystem or combine it with other systems to meet specific operation requirements. This flexibility may allow datacenters to be rapidly adapted to new technologies and regulations which in turn promotes long-term viability and efficiency in the face of evolving industry challenges.
Modular datacenter 10 is scalable and flexible. A builder/operator may choose how large or small to build and have the ability to increase and/or decrease size of modular datacenter 10 as needs change.

Any use herein of any terms describing an interaction between elements is not meant to limit the interaction to direct interaction between the subject elements, and may also include indirect interaction between the elements such as through secondary or intermediary structure unless specifically stated otherwise.

In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be one and only one of the elements.

It will be apparent that changes may be made to the illustrative embodiments, while falling within the scope of the invention. As such, the scope of the following claims should not be limited by the preferred embodiments set forth in the examples and drawings described above, but should be given the broadest interpretation consistent with the description as a whole.

What is claimed is:

1. A modular datacenter, comprising:
at least one cryogenic datacenter module, each of the at least one cryogenic datacenter modules having at least one server block, at least one pipe for providing a heat transfer fluid to and from the at least one server block, each of the at least one server blocks housing at least one server board having at least one data port and a power input;
at least one cooling generator module having a pump, each of the at least one cooling generator modules being in fluid communication with the at least one pipe such that a cooled heat transfer fluid is pumped to the at least one server block and a used heat transfer fluid flows back to the at least one cooling generator module, the used heat transfer fluid being cooled within the at least one cooling generator module; and
a power source in communication with the power input of the at least one server board and the at least one cooling generator module.

2. The modular datacenter of claim 1 wherein the power source is an electrical generation module which generates electricity.

3. The modular datacenter of claim 2 wherein the electrical generation module generates electricity through at least one of a combined heat and power engine powered by natural gas, biogas or hydrogen, fuel cell, solar power, or wind power.

4. The modular datacenter of claim 3 further comprising an electrical energy storage module in communication with the electrical generation module such that an excess electricity is storable within the electrical energy storage module for later use as the power source.

5. The modular datacenter of claim 4 wherein the electrical energy storage module houses at least one battery and at least one supercapacitor.

6. The modular datacenter of claim 1 further comprising a microgrid energy management module for controlling the flow of electricity through the modular datacenter.

7. The modular datacenter of claim 1 wherein the cooling generator module has an absorption chiller for reducing the temperature of the heat transfer fluid.

8. The modular datacenter of claim 1 wherein the cooling generator module has a liquid nitrogen generator for capturing and liquefying atmospheric nitrogen for use as the heat transfer fluid.

9. The modular datacenter of claim 3 further comprising a liquified energy storage, the liquid energy storage having at least one storage tank for natural gas or hydrogen, the at least one storage tank being in fluid communication with the electrical generation module such that a fuel is provided to operate the combined heat and power engine.

10. The modular datacenter of claim 1 wherein each of the at least one server blocks is shaped as a cube.

11. The modular datacenter of claim 1 wherein each of the at least one server blocks are stacked on a series of shelves positioned on a first side wall and a second side wall of the at least one cryogenic datacenter module.

12. The modular datacenter of claim 1 wherein the at least one pipe is positioned under an elevated platform.

13. The modular datacenter of claim 1 wherein each of the at least one server boards are securely mounted on a slotted mounting plate with all of at least one data ports and the power input connected to a DC bus bar.

14. The modular datacenter of claim 1 wherein each of the at least one server blocks has an access panel, the access panel having a first plumbing port for introducing the heat transfer fluid to the at least one server block, a second plumbing port for the heat transfer fluid to flow out of the at least one server block, an electrical port for connection to the power source and the power input of the at least one server boards, and at least one data interface for connection to the at least one data ports of the at least one server boards for storing and computing data.

15. The modular datacenter of claim 1 wherein each of the at least one cryogenic datacenter module and cooling generator module are contained within a shipping container.
